(19) United States
(12) Patent Application Publication
(10) Pub. No.: US 2015/0334824 A1
(43) Pub. Date: Nov. 19, 2015

(54) Multilayer Body Having Electrically Conductive Elements and Method for Producing Same

(71) Applicants: LEONHARD KURZ Stiftung & Co. KG, Furth (DE); PolyIC GmbH & Co. KG, Furth (DE); OVD Kinegram AG, Zug (CH)

(72) Inventors: Walter Fix, Furth (DE); Andreas Ullmann, Zirndorf (DE); Manfred Walter, Nurnberg (DE); Thomas Herbst, Edelsfeld (DE); Ludwig Brehm, Adelsdorf (DE); Achim Hansen, Zug, (ZG) (CH); Andreas Schilling, Hagendorn (ZG) (CH); Haymo Katschorek, Obermichelbach (DE); Norbert Laus, Furth-Burgfarrnbach (DE); Carolin Born, Zirndorf (DE); Andreas Lange, Furth (DE)

(73) Assignees: LEONHARD KURZ Stiftung & Co. KG, Furth (DE); PolyIC GmbH & Co. KG, Furth (DE); OVD Kinegram AG, Zug (CH)

(21) Appl. No.: 14/367,541

(22) PCT Filed: Dec. 21, 2012
(86) PCT No.: PCT/EP2012/076797

§ 371 Date: Jun. 20, 2014

(30) Foreign Application Priority Data
Dec. 23, 2011 (DE) 10 2011 122 152.6

(51) Int. Cl. H05K 1/02; H05K 3/46

(52) U.S. Cl. CPC H05K 1/0274; H05K 3/4664; H05K 2203/107; H05K 2203/095

(57) ABSTRACT

The invention provides a large number of possibilities for how, in the case of a multi-layer body with electrically conductive elements which are not visible to the naked eye, the electrically conductive elements can be prevented from excessively reflecting light back. Here, a suitable surface roughness for the electrically conductive elements can be selected, or at least one additional layer (54) can be provided on the electrically conductive elements (51l).

The invention relates to a multi-layer body with a number of electrically conductive elements, which are provided by electrically conductive material in at least a first layer and when seen in a top view (onto the layer, thus when observed in the direction of the layer sequence) extend in at least one direction of extension (thus perpendicularly to the layer sequence) over a width from the range of between 1 μm and 40 μm, preferably of between 5 μm and 25 μm. The invention also relates to a process for the production of such a multi-layer body.

Because the width of the electrically conductive elements is not larger than 40 μm or is not larger than 25 μm, the electrically conductive elements cannot be recognized with the naked eye. A device with such electrically conductive elements on a transparent support appears transparent as a whole, wherein the transparency is predetermined by the thickness of the electrically conductive elements on the available surface: although the electrically conductive elements reduce the light permeability, they cannot be individually resolved, with the result that as a whole the impression of a transparent object with not quite one hundred percent transparency results.

Such multi-layer bodies are used e.g. in touch panel devices; here the electrically conductive elements are in particular strip conductors by means of which a touch point which an operator touches with his finger can be detected. In the case of such touch panel devices, it is particularly desired if a display device such as e.g. a screen can be seen through the touch panel device. Structures in the touch panel device can then be assigned to individual structural elements in the representation (boxes or buttons), and by touching the touch panel device the operator can then e.g. do the same thing as if he were to use a computer mouse to move the cursor to a corresponding selection box.

Such a touch panel device can also be integrated into a display device.

Another use is to guide the electrically conductive elements through a glass material, wherein they then serve as resistance wires. In the case of a glass pane, in particular in an automobile, it is also not desirable for the resistance wires to be recognized with the naked eye.

The electrically conductive elements do not need to be rectilinear or elongate, but rather can also be present curved, wavy, in the form of points or gridded. The electrically conductive elements can be those elements which have the function of a strip conductor for conducting an electric current. However, they can also be so-called blind structures which are formed from the same material as the strip conductors, but do not take on the function of electrical conduction and rather promote the non-recognizability or non-distinguishability of the strip conductors and thus a homogeneous optical impression and can be present arranged between the strip conductors. In cases of such blind structures, in particular such a punctiform or gridded formation is then also possible.

The distances between the electrically conductive elements can, according to their width, be in a range of between 1 μm and 40 μm, preferably of between 5 μm and 25 μm, but they can also be substantially larger or also substantially smaller.

Although the electrically conductive elements are not visible to the naked eye, they are nevertheless large enough that light striking them is reflected. The effect can thus result that a touch panel device or a glass pane with such a multi-layer body, thus with such electrically conductive elements, reflects light through the electrically conductive elements, without these electrically conductive elements being directly recognizable with the eye. Such an illumination of the strip conductors mainly takes place in the case of observation in the mirror reflection, thus if the angle of incidence of the light corresponds to the angle of observation. In particular, if the electrically conductive elements are formed of metal which also displays the typical metallic gloss in the case of the named small structures, in the case of a surface coverage with a pattern of electrically conductive elements up to 10% of the light striking can be reflected. Such reflections are often undesired.

For instance when the multi-layer body is used in a touch panel device, not only is a high light permeability (transmission) and a non-recognizability and non-distinguishability of the metal pattern desired, but also the impression that the touch panel device reflects light should be avoided. In particular, in the switched-off state a display device behind the touch panel device, the touch panel device should appear homogeneously black.

An object of the invention is to show a way in which a multi-layer body of the type specified at the outset can be formed so that it seems like a conventional light-permeable film to an observer.

The object is achieved in one aspect by a multi-layer body with the features of claim 1 and/or claim 2, in another aspect by a number of processes for the production of the multi-layer body.

The multi-layer body according to the invention with a number of electrically conductive elements which are provided by electrically conductive material in at least first zones of a first layer and when seen in a top view extend in at least one direction of extension over a width from the range of between 1 μm and 40 μm, preferably of between 5 μm and 25 μm, is characterized according to claim 1 in that, due to a measure taken during the production relating to the formation of the first layer and/or the provision and/or suitable formation of a layer different from the first layer, the proportion of the light reflected from the electrically conductive elements (thus the reflectivity) is lower than it would be without the measure, thus for instance in the case of a smooth first layer, without the provision and/or the suitable formation of a specific additional layer different from the first layer.

By the reduction of the proportion of reflected light, the multi-layer body no longer appears reflective, but rather matte or dark, when it is illuminated in the direction of observation. This effect is desired in particular in connection with touch panel devices.

Furthermore, the blackening of the strip conductors also leads to an improvement in the heat emissions of the strip conductors into the environment. This is interesting e.g. when the strip conductors are used as a heating element e.g. for car windscreens. Furthermore, an improved heat emission also leads to an increase in the stability of the strip conductors at higher current densities, as the thermal damage to the strip conductors is reduced by the removal of the heat.

The multi-layer body according to the invention with a number of electrically conductive elements which are provided by electrically conductive material in at least first zones of a first layer and when seen in a top view extend in at least one direction of extension over a width from the range of between 1 μm and 40 μm, preferably of between 5 μm and 25 μm, is characterized according to claim 2 in that the reflectance of visible light with wavelengths from the range of from 400 nm to 800 nm at the electrically conductive elements in the mirror reflection (a) is less than 75%, preferably less than 50%, particularly preferably less than 25%, and/or (b) have a difference of at most 50%, preferably at most 20% from the reflectance of the multi-layer body in second zones without electrically conductive material outside of the first zones in the mirror reflection.

Here too, by the reduction of the proportion of reflected light, the multi-layer body is no longer reflective, but rather appears matte or dark, when it is illuminated in the direction of observation.

In a preferred embodiment, the surface relief structure of the first layer preferably has an average structure depth in the range of from 10 nm to 100 μm, preferably of from 20 nm to 5 μm, particularly preferably of from 50 nm to 1000 nm, quite particularly preferably of from 80 nm to 200 nm. This average structure depth is a measure of the surface roughness.

In respect of the surface relief structure, correlation lengths can be specified, or the lateral extent of the surface relief structure. The correlation lengths and/or the lateral extents of the surface structure of the electrically conductive elements are preferably in a range of between 50 nm and 100 μm, preferably of between 500 nm and 10 μm. Incident light is then not directly reflected, but rather scattered, or absorbed by the surface. For example, plasmons can be excited here.

The first layer preferably has a layer thickness of between 20 nm and 1 μm. It can be provided by conventional application methods, e.g. in the form of a metal layer by vapor deposition or sputter deposition.

In a preferred embodiment of the multi-layer body according to the invention, the first layer is arranged on a support which, on a side facing towards the first layer, has a first surface relief structure with a structure depth at least in the first zones that is large enough that the first layer, on an upper side facing away from the support, has a second surface relief structure which is the through-formed first surface relief structure and thus has a structure depth that is determined by the structure depth of the first surface relief structure, in particular has at least 10% of this structure depth.

Through its surface roughness, the support possibly appears milkily cloudy. In order to suppress this effect, a lacquer layer can be provided on the support at least in second zones which are different from the first zones, thus between the conductive elements, wherein the refractive index of the lacquer layer differs by at most 0.2 and preferably by at most 0.1 from the refractive index of the support. Through this coordination of the refractive indices of the support and lacquer layer with each other, the multi-layer body thus appears transparent; because of the remaining roughness of the first layer, however, its surface retains its light-scattering effect; the refractive index of the electrically conductive material in particular preferably does not match that of the lacquer layer; if the electrically conductive material consists of metal, no additional measures must be taken here.

In particular, the support can be formed multi-layered and can comprise a replication lacquer layer on an actual substrate or on a substrate film, wherein the first surface relief structure is then molded in this replication lacquer layer.

The first surface relief structure can be formed, at least in areas, as a matte structure, a regular structure, in particular a grating and/or a refractive structure. It can further be an asymmetrical structure, a lens-like structure or a combination of the structures named above. In a preferred variant, the surface relief structure is a matte structure with stochastically distributed relief structures and/or stochastically selected relief parameters, wherein the relief parameters in particular relate to the lateral width dimension, the length dimension and the structure depth. The lateral dimensions are typically between 50 nm and 400 nm. The average structure depth is between 40 nm and 10 μm.

The second surface structure can be formed, at least in areas, as such a structure molded into the first layer which deflects the incident light by diffraction and/or reflection. In this connection, an area is an area which can be identified by a top view of the multi-layer body and thus the layer. In an embodiment example, the second surface structure is, at least in areas, a matte structure, in particular with correlation lengths of between 200 nm and 100 μm and an average structure depth of preferably 50 nm to 10 μm, particularly preferably 50 nm to 2000 nm. In a second embodiment, the second surface is formed, at least in areas, as a diffractive structure, in particular as a hologram and/or a Kinegram®, and in a third embodiment the second surface structure is molded into the first layer, at least in areas, as a moth-eye structure, in particular as a cross grating and/or a linear grating with a grating period of between 100 nm to 400 nm and an average structure depth from the range of from 40 nm to 10 μm.

The surface structure can be formed such that the recesses which cause the roughness become narrower from the surface into the depth of the material. However, they can also be formed such that cavities are shaped underneath the actual surface in which, for example, incident light is subjected to a high degree of multiple reflection and absorption.

It is also possible that additional metallic partial areas are formed as visually recognizable markings, such as e.g. logos, trade names or security elements, such as e.g. KINEGRAM®.

The embodiments named for providing the second surface relief structure can also be combined with each other: in some areas, one measure can be taken, in other areas the other measure.

In this embodiment, the molding of the second surface relief structure can be carried out directly into the material of the first layer, but it can also be determined by the surface relief structure underneath it of a, or the, support. By a change in the surface structure, or roughness, of the electrically conductive elements, the advantage results that the conductivity of the electrically conductive elements can also be varied depending on the choice of the matte structure. It is thus preferably provided that, due to the formation of the surface, in particular through a variable thickness, of the first layer this has a conductivity which varies in areas. In this connection, an area is an area which can be identified by a top view of the multi-layer body and thus the layer.

In another preferred embodiment of the invention, which, however, can be implemented simultaneously with the preferred embodiments mentioned, the electrically conductive material of the first layer has metal, and on the first layer a non-metallic compound of this metal is arranged. The non-metallic compound does not shine, with the result that it appears dark or has a reflection-reducing effect.

Through redox reactions of the metal, the non-metallic compound can be directly produced. For example, the metal can be oxidized, a metal oxide is thus obtained on the metal of the first layer. Equally, the metal can be reacted to form a sulfide, which in particular can occur easily if the metal comprises silver or copper. The metal sulfide is then arranged on the metal of the first layer. The metal of the first layer can also be chromated. Furthermore, it can comprise aluminum which is anodized. Examples of such compounds are AgO, Ag₂O, Ag₂O₃, Ag₃O₄, Ag₂S, CuO, CuS, Cu₂S, Al₂O₃ (optionally pigmented with colorants).

Instead of a chemical compound on the metal, at least one metal layer can alternatively or additionally be provided on the first layer. For example, such a metal can be used which has a greater surface roughness or absorbs more light than the material for the first layer. For instance, if the electrically conductive material of the first layer comprises silver, a metal layer of chromium can be applied to this, e.g. by vapor deposition or sputter deposition, and this chromium then appears grayish and reduces the reflection of the metallic strip conductors. Equally, several metal layers can also be applied at once.

In a multi-layer body of the type according to the invention, it is preferably provided, optionally in combination with one of the other embodiments, that a colored layer is located on or underneath the first layer. Reflections are reduced by the colored layer.

In a preferred variant of this, a support is provided on which the first layer is arranged. A material which provides the colored layer adheres more poorly to the support, due to its chemical properties and/or its surface structure and/or a structured layer between the support and the first layer, than to the first layer. As a result, the colored layer can be arranged specifically in the area of the electrically conductive elements.

In particular, the colored layer can comprise photoresist or be provided by photoresist. By photoresist is meant a light-sensitive lacquer which, when irradiated with high-energy radiation, e.g. UV radiation or electron radiation, either cures in the irradiated areas and becomes particularly resistant to later washing processes with alkaline or acid, or becomes particularly unresistant to later washing processes with alkaline or acid in the irradiated areas. Colored photoresist can in particular be used for structuring, with the result that the same photoresist which provides the colored layer can also be used in at least one production step for the multi-layer body.

In a further embodiment of the multi-layer body according to the invention, which can be combined with the other preferred embodiments, a semiconductor layer is located on or underneath the first layer at least in areas. Such a semiconductor layer can also reduce the reflections in the areas in which it is provided. The semiconductor layer can consist of inorganic material, preferably of zinc oxide or aluminum-doped zinc oxide, and equally the semiconductor layer can also consist of organic material.

In a preferred variant of all embodiments with a further layer (non-metallic compounds, metal layer, colored layer or semiconductor layer), an intermediate layer is provided between the respective additional layer and the first layer.

In the multi-layer body, also in all previously named embodiments, it is preferably provided that a layer which is light-impermeable in areas and light-permeable in areas is arranged underneath the first layer. Such a layer can be used in the framework of an exposure of a photoresist and remain in the multi-layer body. This layer preferably comprises a gelatin layer with silver and silver oxide particles or is provided as a layer of ink.

In a manner known per se, the electrically conductive material comprises at least one from the group of silver, gold, copper, chromium, aluminum, mixtures of these materials, in particular alloys, as well as suitable organic compounds with movable charge carriers such as polyaniline or polythiophene and another doped organic semiconductor material.

As stated at the outset, the electrically conductive elements are preferably provided in the form of strip conductors which are linear, bent, punctiform or gridded.

To achieve the object, a display device and/or a touch panel device with such a multi-layer body with electrically conductive elements in the form of strip conductors is also provided. Alternatively, a glass pane is provided with a multi-layer body of this type to provide a resistance wire functionality.

The named preferred embodiments of the multi-layer body can be realized simultaneously on one and the same multi-layer body, in that one measure is realized in first areas and the second measure is realized in second areas. For example, in a first area the first layer can have a high surface roughness and in another area an additional layer can be provided, for instance a color layer or metal oxide layer; or metal oxide layers can be provided in a first area and in another area a colored photoresist layer etc. Further combinations, also with more than two different areas, are possible.

The processes according to the invention for the production of a multi-layer body with a number of electrically conductive elements which are provided by electrically conductive material in at least in a first layer and when seen in a top view extend in at least one direction of extension over a width from the range of between 1 μm and 40 μm, preferably of between 5 μm and 25 μm, to which end a suitable structuring step is to be carried out in the production process, in each case realize a measure to reduce the reflectivity of the electrically conductive elements in different ways.

The process according to a first aspect of the invention for the production of a multi-layer body comprises applying the electrically conductive material to a support, wherein according to the invention a) the support has such a high surface roughness that it determines the surface roughness of the first layer and/or b) the material providing the first layer is subjected to a treatment to increase its surface roughness.

In both alternatives, the result is a relatively high surface roughness of the first layer and thus a suitable reduction in the reflectivity of the first layer. Either the high surface roughness of the first layer is determined by the support, and alternatively or additionally the high surface roughness of the first layer is also brought about on this in a targeted manner.

Preferably, in case a) of a support with high surface roughness, a lacquer layer is applied, wherein the unevenness of the support is balanced out by the lacquer, with the result that the multi-layer body does not appear so milkily cloudy as the support seen on its own. The refractive index of the lacquer layer here is to differ by at most 0.2, preferably by at most 0.1 from the refractive index of the support.

The support can be selected to already be suitable, but in a preferred embodiment the support is subjected to a treatment to increase its surface roughness, in particular by mechanical brushing, calendering with rough rollers, by ion beam treatment and/or plasma treatment.

In a variant, the surface of the support becomes microstructured or nanostructured or an additional layer which is microstructured or nanostructured is applied to the support before the electrically conductive material for the first layer is applied.

Such a structuring can take place thermomechanically or by stamping and using ultraviolet radiation, alternatively or additionally the additional layer can be sprayed on, applied by inkjet printing or another printing process (with silica-gel-filled lacquer), and further alternatively or additionally the additional layer can first be applied in at least one partial area over the whole surface and then be structured using photoresist (negative etching or positive etching).

As far as the treatment of the first layer is concerned, this can take place chemically by lasers and/or mechanically, the latter in particular by rubbing, sanding and/or brushing.

The corresponding treatment of the material which provides the first layer can take place before a structuring to form the electrically conductive elements, but also subsequently, after this structuring.

According to a second aspect of the invention, a process for the production of a multi-layer body of the type named is provided, wherein the electrically conductive elements are provided by metal in the first layer. According to the invention, it is provided that a) a surface of a metal for the first layer is treated chemically, so that it appears darker and/or scatters light more pronouncedly, and/or that b) a further layer is provided over and/or underneath the first layer which appears darker and/or scatters light more pronouncedly than the metal of the first layer.

The chemical treatment of the surface of the metal and the further layer ensure that the reflectivity of the metal is reduced.

In a first variant of this embodiment, the metal for the first layer is subjected to a chemical treatment, in particular a redox reaction.

Either the reactant for the redox reaction can be fed in from outside, which can have advantages in order to optimally configure the metering or, alternatively, in the process the metal can be applied to an underlayer which already comprises a reactant for the redox reaction. This reactant then passes from the underlayer to the surface of the metal facing towards the underlayer. This procedure can be promoted, in particular the release of the reactants from the underlayer can be brought about by the action of heat, and equally a predetermined period can also be waited.

In the embodiment of providing a further layer, according to a first variant this can be applied by coating, printing, doctor-blading and/or centrifuging and these processes are particularly efficient.

The further layer can be promoted to deposit selectively on the metal, in that in particular a) a material for the further layer is selected which adheres to the surface of the metal of the first layer due to a selective chemical reaction, and/or b) the further layer is provided by solid particles which adhere to the metal, optionally accompanied by promotion of the adhesion behavior, and/or c) a support for the first layer (onto which this is applied) the metal for the first layer and the material for the further layer match one another such that an adhesion behavior of the support ensures that the material for the further layer does not adhere to it and an adhesion behavior of the metal ensures that the material for the further layer adheres to it, wherein preferably the material of the support and/or a microstructure or nanostructure on its surface determines the adhesion behavior here, and/or

d) the metal for the electrically conductive elements is heated to a temperature at which the material for the further layer melts, and/or
e) photoresist is used for a structuring.

All these preferred variants of promoting the deposition of the further layer on the metal result in the further layer being provided in the multi-layer body in a form which corresponds to the metal structure. The structuring of the further layer can thus also be predetermined by the metal structuring.

In the named variants, the further layer can be applied before a structuring of the metal layer and be structured together with this. It is particularly efficient if the further layer is provided in the form of photoresist for structuring (which is colored and therefore appears darker, or scatters the light more pronouncedly than the metal), and if the photoresist is further left on the metal after the structuring.

Alternatively it is possible that the further layer is applied after a structuring of the metal layer. Here too, photoresist can be used in order to provide the further layer, wherein the photoresist is then applied uninterrupted at least in areas, thus is applied over the whole surface, but then is exposed by the structured metal layer and is removed in the exposed areas. Here too, the photoresist remains on the metal, but the photoresist is not used itself for structuring, but rather inversely the metal layer is used for the structuring of the photoresist registered relative to the metal layer.

In an alternative variant of the preferred embodiment, the (at least one) further layer comprises a color layer which is applied to and structured on a support before the metal of the first layer, and wherein the metal is then only applied onto the structured parts of the color layer. For example, it is possible, by means of a laser printing process, to print dark layers with a defined structure and then to selectively transfer metal onto this dark layer via a transfer process and thus to produce the electrically conductive elements (for instance in the form of strip conductors). The use of further transfer layers may be necessary here, and for example a thermal transfer process or a cold stamping process can be used.

In a variant of the process according to the second embodiment, the (at least one) further layer is provided by a semiconductor material which in particular comprises zinc oxide or aluminum-doped zinc oxide.

Furthermore, an intermediate layer can be applied between the application of the further layer and the application of the metal for the first layer. (Either the further layer is applied first here, then the intermediate layer and then the metal, or inversely the metal is applied first, then the intermediate layer and then the further layer). The further layer is spaced apart from the metal by the intermediate layer. This can e.g. be advantageous for chemical reasons if the further layer comprises a metal oxide.

According to a third aspect of the invention, a process for the production of a multi-layer body with a number of conductive elements is provided, wherein these conductive elements are provided by silver in the present case, and when seen in a top view extend in an extension layer over a width in the range of between 1 μm and 40 μm, preferably of between 5 μm and 25 μm, wherein according to the invention the silver, together with oil, in particular paraffin oil or silicone oil, is evaporated and it is caused to be deposited on a support. By the addition of an oil to the material to be evaporated, a black coloration of the resulting silver layer takes place, without the electrical properties thereof being disadvantageously affected.

In a fourth aspect of the invention, a process for the production of a multi-layer body with a number of electrically conductive elements is provided, wherein these electrically conductive elements are provided by electrically conductive material in a first layer, and when seen in a top view extend in at least one direction of extension over a width in the range of between 1 μm and 40 μm, preferably of between 5 μm and 25 μm, wherein according to the invention a masking layer with light-impermeable and light-permeable areas is applied to a support and either a) a photoresist layer is applied to the masking layer and a metal layer onto this or b) a metal layer is applied to the masking layer and a photoresist layer onto this, and wherein the photoresist further is exposed through the masking layer and is removed i) in the exposed or optionally also ii) in the unexposed areas.

Through the provision of the masking layer as a part of the multi-layer body itself, a particularly precise structuring of the electrically conductive elements can be ensured. A light-impermeable area remains underneath the structured metal layer and ensures that the reflectivity of the metal layer is reduced in comparison with a smooth metal layer without the masking layer underneath it.

The processes according to the invention can be combined with each other, because one measure can be provided in partial areas of the multi-layer body, and the other measure in other partial areas. A process for the production of a multi-layer body is thus preferably provided that simultaneously comprises the features according to one of the claims from two of the groups, of which the first group comprises claims 34 to 41, and the second group comprises claims 42 to 55, and the third group comprises claim 56 and the fourth group comprises claim 57.

In all processes according to the invention, the multi-layer body is preferably transferred to a substrate as a whole, wherein the layer provided most recently is contiguous to the substrate. In this way, an inversion of the sequence of the layers for the observer can take place by a transfer process.

Preferred embodiments of the invention are described in more detail below with reference to the drawings, in which

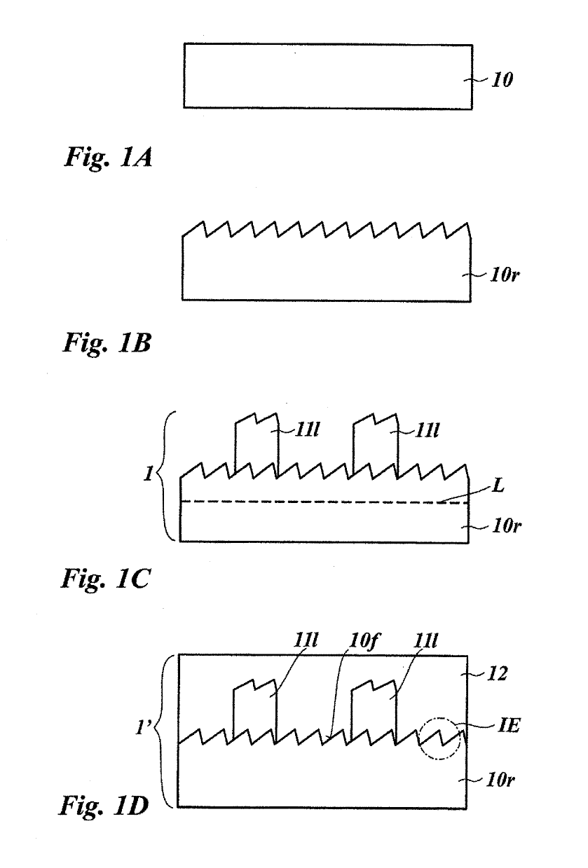

FIG. 1A to FIG. 1E serve to explain the individual steps of a process according to a first aspect of the invention with reference to sectional views through a multi-layer body 1,

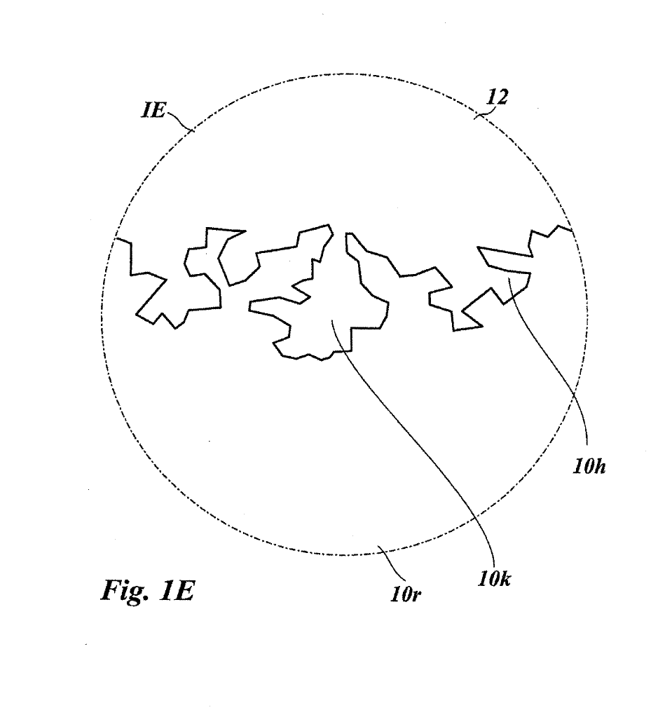

FIGS. 2A to 2C serve to explain the individual steps of a process according to a second aspect of the invention with reference to sectional views of a multi-layer body 2,

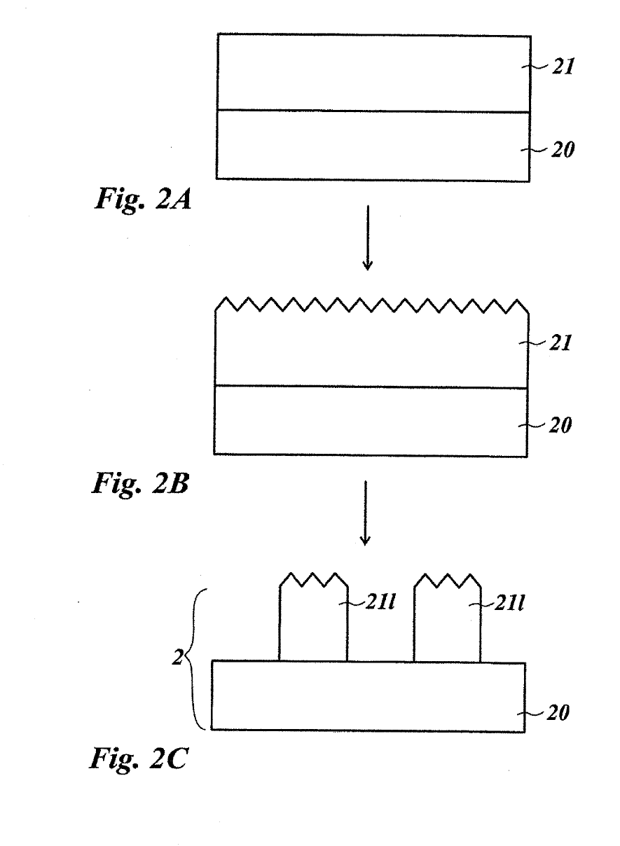

FIG. 3A to FIG. 3C serve to explain the individual steps of a process according to a third aspect of the invention with reference to sectional views of a multi-layer body 3,

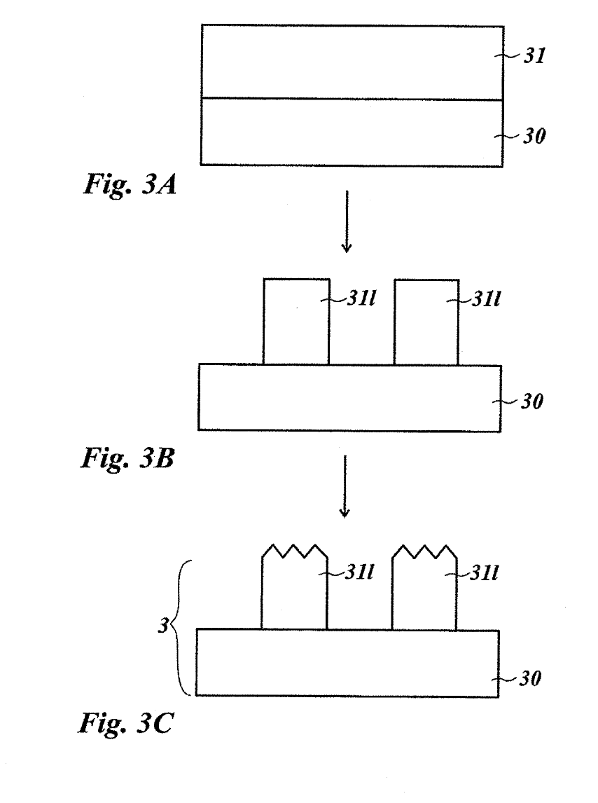

FIG. 4A to FIG. 4B serve to explain the individual steps of a process according to a fourth aspect of the invention with reference to sectional views of a multi-layer body 4,

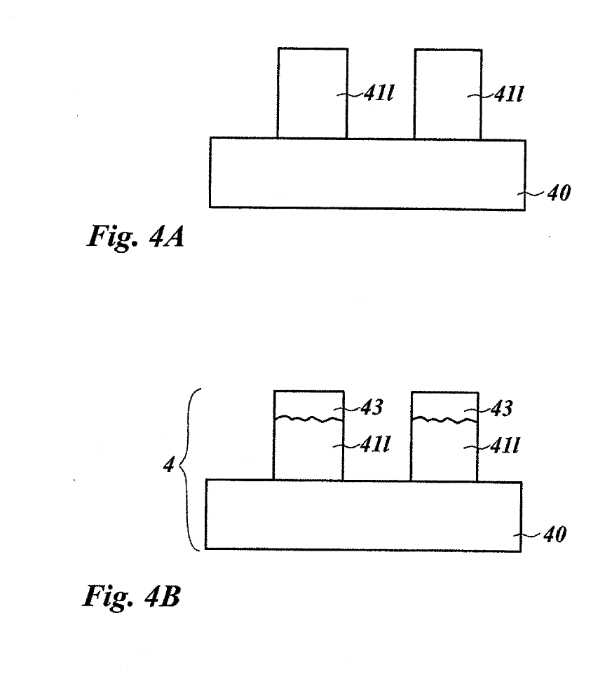

FIG. 5A to FIG. 5B serve to explain the individual steps of a process according to a fifth aspect of the invention with reference to sectional views of a multi-layer body 5,

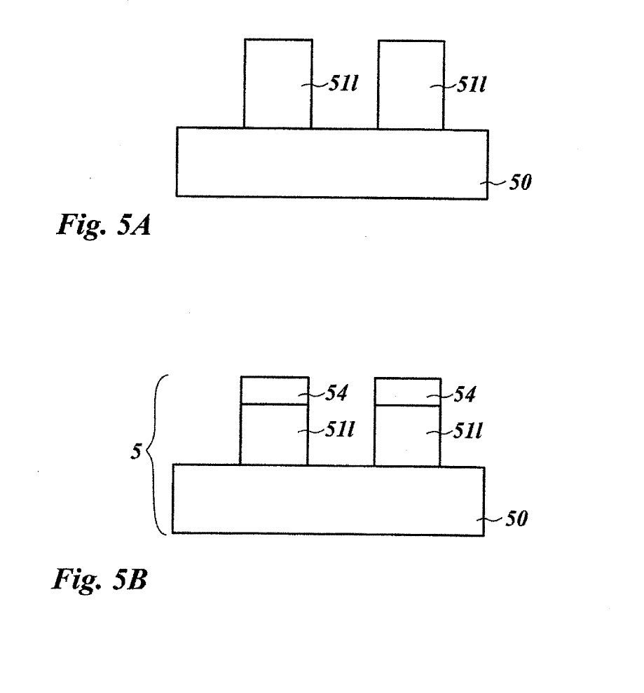

FIG. 6A to FIG. 6E serve to explain the individual steps of a process according to a sixth aspect of the invention with reference to sectional views of a multi-layer body 6,

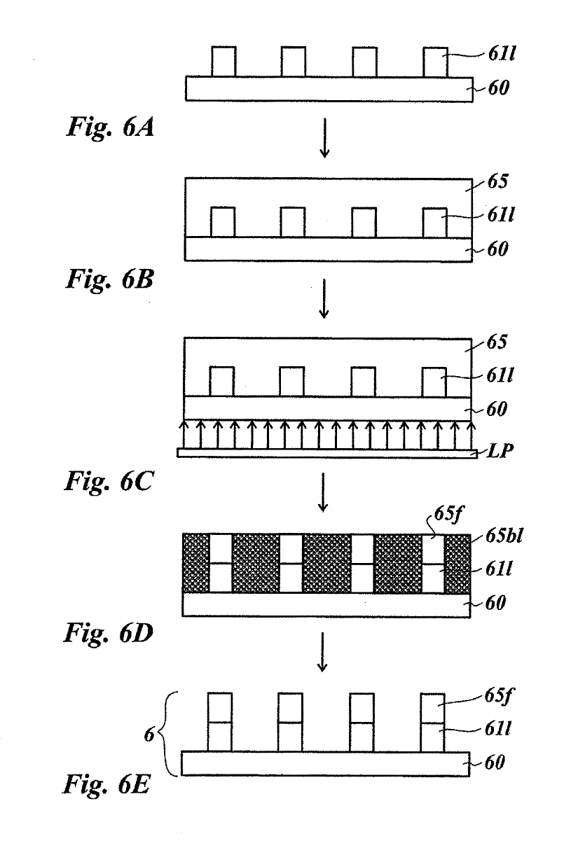

FIG. 7 shows a section through a multi-layer body 7 according to a seventh aspect of the invention,

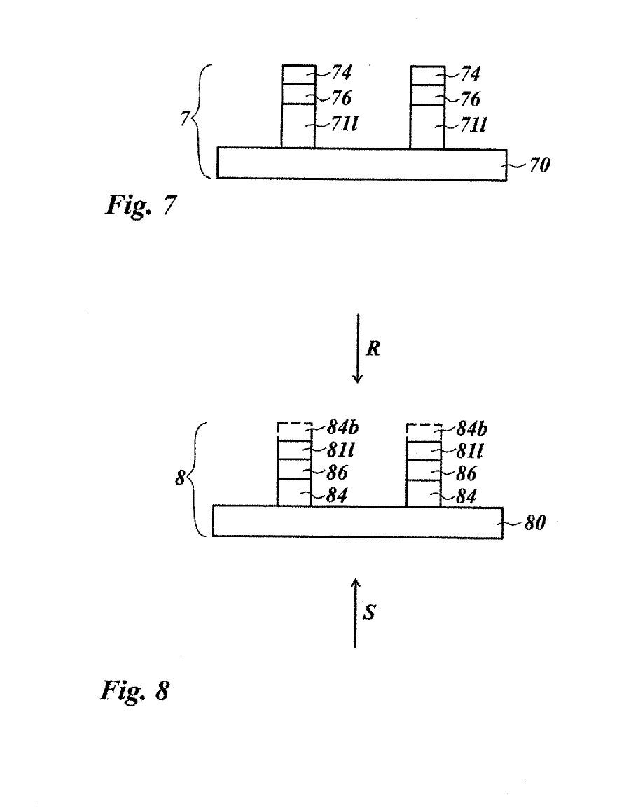

FIG. 8 shows a section through a multi-layer body 8 according to an eighth aspect of the invention,

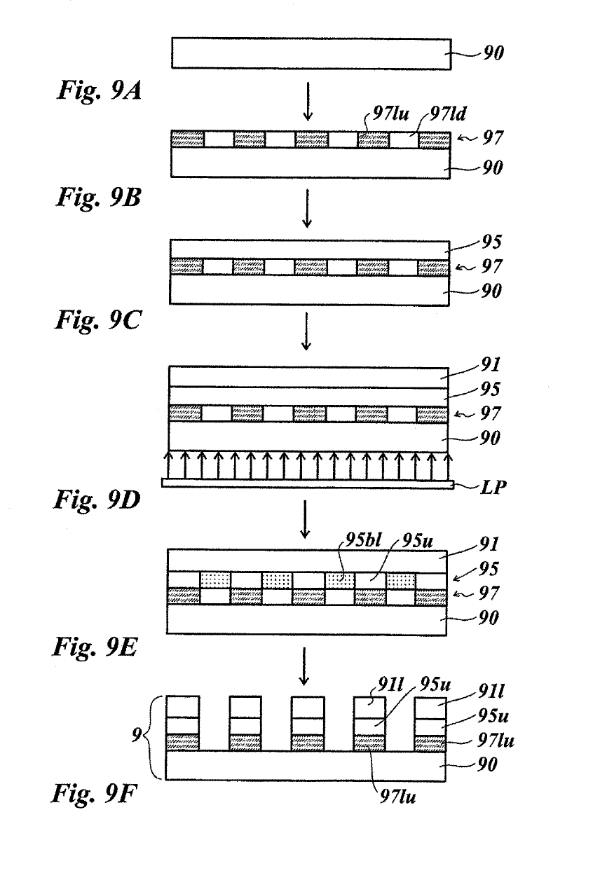

FIG. 9A to FIG. 9F serve to explain the individual steps of a process according to a ninth aspect of the invention with reference to sectional views of a multi-layer body 9,

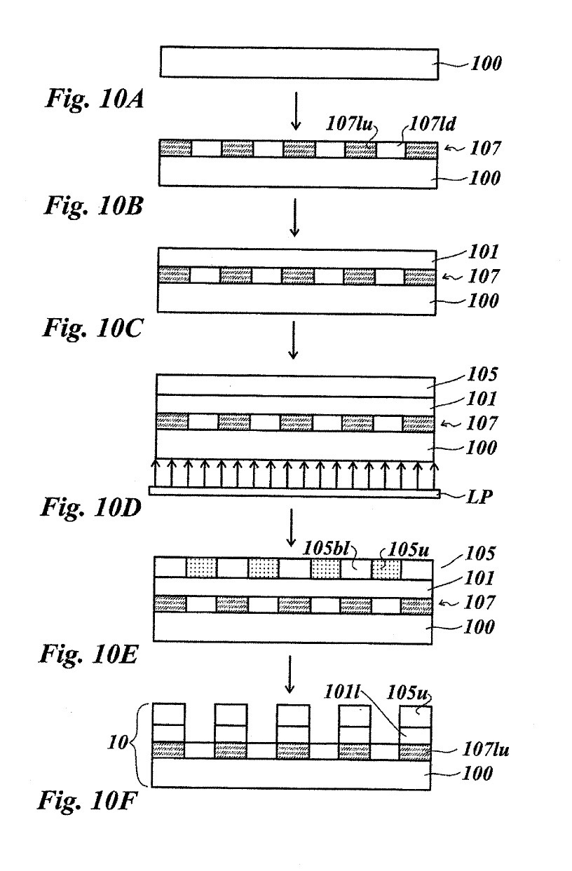

FIGS. 10A to 10G serve to explain the individual steps of a process according to a tenth aspect of the invention with reference to sectional views of a multi-layer body 10, and

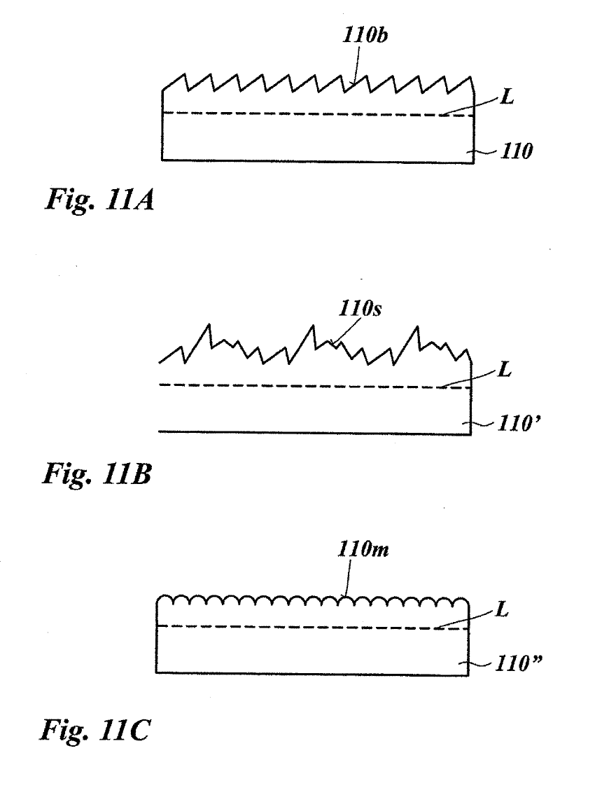

FIGS. 11A to 11C serve to explain possible surface structures.

In the present case, a number of strip conductors of electrically conductive material are to be provided on a substrate, for example for a touch panel device, wherein the strip conductors are to have a width from the range of between 1 μm and 40 μm, preferably of between 5 μm and 25 μm. The strip conductors are thus not visible to the naked human eye, but rather only contribute slightly to the reduction of the transparency of the device as a whole. Measures are now presented here for how the strip conductors can be prevented from excessively reflecting light back in the mirror reflection, with the result that the device would retain a slight gloss; rather, this gloss is suppressed. When reference is made in this application to an upper and a lower layer, this relates to the arrangement of the touch panel device: the upper layer faces towards an observation side, the lower layer faces away from an observation side. However, it is not absolutely necessary that the layers are produced in order from bottom to top in production. Rather, a transfer process can ensure that the layers are provided in exactly the inverse manner from the manner in which they are arranged later.

A first embodiment of a process for the production of a multi-layer body 1 begins with the provision of a transparent substrate 10. In a subsequent processing step, this substrate is provided with a surface roughness, for instance by mechanical brushing, calendering with rough rollers, ion beam treatment, plasma treatment or chemical etching (for instance with trichloroacetic acid), with the result that the situation shown in FIG. 1B results and the substrate 10 becomes substrate 10r (“rough”). The substrate (10r) can also optionally be provided immediately at the beginning of the process. A metal layer is now applied to the substrate 10r over the whole surface and then structured by known demetallization processes, e.g. etching or washing, i.e. removed in parts of the surface, with the result that the electrical strip conductors result, see the metal islands 11l shown on the substrate 10r in FIG. 1C. Through the structuring, the metal islands 11l are located in first zones of the multi-layer body 1, the intermediate spaces between them in second zones of the multi-layer body 1.

The metal is applied for example by vapor deposition or sputter deposition, and then the surface roughness of the substrate 10r is reflected in a corresponding surface roughness in the metal layer 11l with the islands.

The roughness of the metal layer 11 is defined by an average structure depth from the range of from 10 nm to 10 μm, preferably 20 nm to 2 μm, further preferably 30 nm to 500 nm, further preferably 80 nm to 200 nm.

In the case of this surface roughness, incident light is scattered or absorbed and in any case not reflected smoothly back, with the result that reflections are prevented effectively. The process can optionally be continued after the step leading to FIG. 1C, in that a lacquer layer 12 (FIG. 1D) is applied, which has the same refractive index as the substrate 10r, with the result that the surface of the substrate 10r which is still free in areas 10f due to the structuring of the metal layer 11 does not impair the transparency.

The roughness provided in the substrate 10r can be purely random, but, as shown in FIG. 11A, a regular blazed grating structure 110b can be provided on the carrier substrate 110; as shown in FIG. 11B, a statistical matte structure 110s, e.g. a matte structure with stochastically distributed relief structures, can be provided on the substrate 110′; and, as in FIG. 11C, a surface structure 110m can be provided which shows the moth-eye effect in the case of the substrate 110″.

Due to a nanoporous surface structure, the roughness provided in the case of the substrate 10r can in particular be provided with indentations or undercuts and cavities. Such nanoporous surface structures can also be produced by physical processes, such as e.g. plasma treatments, or also by chemical processes, such as etching/roughening by trichloroacetic acid treatments.

FIG. 1E shows such a surface of the substrate 10r in an exemplary case; here the cut-out section IE from FIG. 1D is represented magnified in FIG. 1E. In the present case, a cavity 10k is filled by the lacquer 12, an undercut 10h is likewise reached by the lacquer 12. When choosing the lacquer for the lacquer layer 12, care must be taken that its viscosity (toughness) and its drying behavior are selected such that a good filling of the valleys, cavities 10k and undercuts 10h is ensured during the processing operation. For example, lacquers which are too viscous would only enter the cavities to an insufficient extent and would not fill them.

Except for the embodiment in which the lacquer has substantially the same refractive index as the substrate 10r (namely its refractive index differs from this by at most 0.2 and preferably by at most 0.1), it can also be provided that the refractive index of the lacquer is between that of the substrate 10r and that of the surrounding air. In this case, the change in the refractive index between air and substrate 10r takes place in two stages and thus more continually. This determines an additional anti-reflective effect. However, it is to be borne in mind that as the difference between the refractive indices of lacquer and substrate 10r increases, the so-called haze value also increases. However, depending on the specification for the maximum haze value which can be tolerated, the reflectivity can be minimized by suitable choice of the refractive index of the lacquer.

In the case of a nanoporous substrate 10r, it is advisable to form the metal layer 11l in a thickness of at least 100 nm, preferably 150 nm, but usually less than 200 nm. The desired dark impression of the metal layer 11l results due to multiple reflections of the incident light on the pronouncedly rugged and metal-covered surface. In the case of very small dimensions in the structures of less than 100 nm, due to the metal covering it is to be assumed that plasmonic effects also contribute considerably to an increased absorption of electromagnetic radiation. Electromagnetic radiation with a wavelength in the order of magnitude of the metallic structures leads here to the excitation of quantized oscillations of the electron gas of the metal with respect to the stationary atomic cores. The excitation of such plasmons represents a very effective absorption mechanism for visible light, wherein in particular in the case of self-similar metallic structures the energy present in the plasma oscillations is dissipated particularly well.

In addition to the sufficient thickness of the metal layer 11l, it should also be ensured that the width of the individual islands in the metal layer is substantially larger than the individual structural elements in the nanostructure. In the case of lateral dimensions of 50 nm to 100 nm of a statistical nanostructure and an average structure depth from the range of from 50 nm to 1 μm it is desirable if the metallic islands 11l has a width from the range of between 1 μm and 40 μm, preferably of between 5 μm and 25 μm, so that a continuous conductivity in the metal layer 11l is ensured, even if the metal film is locally repeatedly interrupted by nanostructures in the pronouncedly rugged surfaces.

The surface roughness can be imparted directly to the substrate 10r, or 110, 110′, 110″, but it can also be stamped a separate layer which is applied to the substrate 10, 110, 110′, 110″, as illustrated by the dashed line L.

In a modification of the process described with reference to FIGS. 1A to 1E, a metal layer 21 can also be applied over the whole surface at least in partial areas onto a support 20 with an even surface, as shown in FIG. 2A, and then it is possible to proceed to the situation according to FIG. 2B, in which the metal layer 21 once again has a greater surface roughness according to the above-named numeric values. The treatment of the surface of the metal layer can take place by etching of the metal by means of acid, by laser structuring of the surface, or by a mechanical surface treatment, in particular rubbing, sanding or brushing, etc. After the surface treatment, the situation according to FIG. 2C is produced, thus the layer 21 is structured, with the result that the strip conductor elements 211 result.

In a modification of the embodiment according to FIG. 2A to FIG. 2C, it can be provided that, with the same starting situation as in FIG. 2A with a metal layer 31 on a support 30, the metal layer 31 is structured first, with the result that the strip conductor elements 31l result, and then the surface treatment of the metal layer 31 is carried out, with the result that the strip conductor elements 31l subsequently have a rough surface, as in FIG. 3C, with the result that the situation shown in FIG. 2C results.

Instead of roughening the surface of the metal layer in order to ensure that the reflectivity is minimized, a further material provided in addition to the metal can also ensure that the reflectivity is minimized.

Thus, in a fourth embodiment, shown in FIGS. 4A, 4B, of a process for the production of a multi-layer body 4 a metal layer is applied to a support 40 first, and then structured, with the result that the strip conductors 41l result, and subsequently the surface of these strip conductors 41l is subjected to a redox reaction, with the result that a part of the metal layer of the strip conductor 41l forms a new layer 43. For example, the metal can be oxidized, so that an oxide layer results as layer 43; equally, if the metal consists of silver or copper, a sulfide of this material can be produced (thus silver oxide or copper oxide), the metal can be chromated, and finally aluminum can be anodized as material for the strip conductor 41l.

The thus-formed layer 43 scatters more pronouncedly and is darker than the metal structure underneath it.

As an alternative to chemical treatment of the metal layer, a further layer can also be easily applied to the metal layer. This is illustrated with reference to FIGS. 5A and 5B:

Strip conductors 51l are located on a support 50 and a further layer 54 is applied onto these, e.g. by means of conventional coating methods, by means of printing, doctor-blading, centrifuging, etc. In particular, a dark color is selected for the further layer 54.

The substrate 50 and the metal 51l have e.g. a different wettability, wherein the wetting behavior of a colored lacquer which provides the layer 54 is selected such that this adheres well exclusively to the strip conductors 51l. A colored lacquer for providing the layer 54 can adhere to the strip conductors due to a selective chemical reaction with the metal surface. Instead of a liquid dye which cures through drying, solid dye particles can also be applied to the strip conductors 51l, which adhere to the strip conductors 51l and are optionally also processed in order to improve the adhesion, such as e.g. by exposure to temperature. An application in analogy to xerography or a laser printing process is also conceivable, thus the selective electrostatic deposition of dark-colored toner particles onto surfaces.

The layer 54 can also be applied selectively to the strip conductors 51l by means of a thermal transfer principle, e.g. the strip conductors can be heated selectively by a lamp, wherein melted chromophoric material is preferably deposited on the hot strip conductors 51l.

By nanostructuring or microstructuring of surfaces of the metal 51l or of the support 50, the wetting behavior of the surfaces thereof can also be varied and thus the selective accumulation of the material to be printed can be controlled, to improve the adhesion of the colored lacquer.

Finally, a structuring using photoresist (positive etching, negative etching, washing processes, etc.) is also possible.

The roles of color layer 54 and strip conductors 51l can also be exchanged (not represented, by the color layer being structured first applied to a support and then strip conductors being constructed only at those locations which are printed with the color layer). For example, it is possible to print layers of darker color with a defined structure by means of a laser printing process and then to transfer metal selectively onto these layers using a transfer process and thus to produce strip conductors.

Instead of a pure color layer, the layer 54 can also be a semiconductor layer, e.g. be of zinc oxide or aluminum-doped zinc oxide which is applied e.g. by means of sputtering.

The layer 54 can equally well also be another metal, e.g. in the case of strip conductors 51l of silver, chromium, which is vapor-deposited or sputter-deposited.

A layer applied to the strip conductors can also be a dark-colored photoresist layer. The photosensitive properties of the photoresist can be used here in the production of the multi-layer body, as becomes clear with reference to FIGS. 6A to 6E:

Strip conductors 61I are located on a substrate 60. This is shown in FIG. 6A. As can be seen in FIG. 6B, a layer 65 of dark-colored photoresist is now applied to this whole.

By means of a lamp LP (FIG. 6C), the photoresist layer 65 is now exposed through the side of the substrate 60, with the result that the strip conductors 61l serve as shadow casters. As can be seen in FIG. 6D, areas above the strip conductors 61l, the areas 65f, are unexposed, whereas the areas 65bl are exposed. If the exposed photoresist 65bl is now removed, the strip conductors 61l remain on the substrate 60 with the areas 65f of the photoresist on them in the form of islands. Substantially the same situation as in FIG. 5B is thus obtained, wherein the layer 54 is provided in the form of a photoresist layer.

A dark layer does not necessarily have to follow the metal layer in the layer sequence. Thus, as shown in FIG. 7, a number of strip conductors 71l can be provided on a support 70, on these then an intermediate layer 76, and on the intermediate layer 76 the additional layer 74 can be provided.

The darkening layer can also be provided underneath the metal layer, as is shown for example in FIG. 8.

A color layer 84 is located on a support 80, on this layer an intermediate layer 86, and then on this the strip conductors 81l. If the thus-constructed multi-layer body is now viewed from the direction R, and if this is illuminated from the direction S, the color layer 84 prevents so-called ghost images: this is because without the color layer 84, reflections on the back side of the metal layer and the renewed reflection thereof e.g. on boundary surfaces of the substrate could lead to an undesired optical impression also in forward direction. An additional layer 84b can also optionally be located on the metal layer 81l and thus prevent undesired reflections of reflected light. For example, the layer 84b, in the form of an oxide layer, can also protect against environmental influences (oxidation, water, UV radiation) as a barrier layer.

In a ninth embodiment, shown in FIGS. 9A to 9F, of a process for the production of a multi-layer body 9, a masking layer 97 which has light-permeable areas 97ld and light-impermeable areas 97lu is applied first to a substrate 90, compare FIG. 9B.

As shown in FIG. 9B, a photoresist 95 is applied to this masking layer 97, with the result that the situation shown in FIG. 9C results, and a metal layer 91 is applied to the photoresist 95 in the next step to produce the situation shown in FIG. 9D.

The layer structure according to FIG. 9D is now exposed using the lamp LP from below according to the arrows, with the result that, in the layer of the photoresist, exposed areas 95bl and unexposed areas 95u result.

The exposed photoresist 95bl can now be removed in the framework of a lift-off process, e.g. by a simple washing solution or by chemical means, with the result that the situation shown in FIG. 9F is produced: islands 95u of photoresist are located on the light-impermeable areas 97lu, and islands 91l, which form the desired strip conductors, on them.

The masking layer 95 here, or its light-impermeable areas 97lu, causes the strip conductors 91l not to appear excessively reflective. The masking layer 97 thus has a dual function, because on the one hand it has a role in the production of the multi-layer body, and on the other hand it has a role in the finished multi-layer body 9.

In a modification of the ninth process for the production of a multi-layer body 9, a process for the production of a multi-layer body 10 can be carried out, which is described below with reference to FIGS. 10A to 10F:

A substrate 100 is provided with a layer 107 as masking layer, which has light-permeable areas 107ld and light-impermeable areas 107lu. Unlike in the ninth process, in this tenth process a metal layer 101 is now applied first to the layer 107, with the result that the situation shown in FIG. 10C results, and only then is a complete photoresist layer 105 applied to the metal layer 101 to produce the situation shown in FIG. 10D. If illumination is now carried out by means of the lamp LP from below according to the arrows, the masking layer 107 thus appears as a mask, but the light likewise penetrates the metal layer 101, with the result that the photoresist is exposed in areas 105bl and is unexposed in areas 105u which are in the shadow of the light-impermeable areas 107lu. (For this, the metal layer can consist e.g. of silver and be 100 nm thick.)

This situation shown in FIG. 10E gives way to the situation shown in FIG. 10F, when the exposed photoresist is removed and then an etching step is carried out. Here too, island-shaped strip conductors are obtained, wherein, unlike in FIG. 9F, the photoresist 105u is located above the strip conductor 101l and not below.

In the present case, however, it does not depend on the photoresist, because the light-impermeable areas 107lu ensure that the strip conductors do not appear objectionably reflective.

The named ten processes according to the invention can also be combined with each other, for example a first layer structure can be provided in one area of the multi-layer body and a second layer structure can be provided in a second area. Different production processes can then be used for each layer structure.

In the present case, it was discussed that the electrical strip conductors consist of metal. This metal can in particular be silver, gold, copper, chromium or aluminum. Alternatively, alloys of these metals can be provided. Non-metallic, but electrically conductive strip conductors, for instance of a doped semiconductor material, can also be provided. With the exception of the process containing the redox reaction of the metal, all other processes can also be carried out with this semiconductor material.

1. A multi-layer body with a number of electrically conductive elements, which are provided by electrically conductive material in first zones of at least a first layer and when seen in a top view extend in at least one direction of extension over a width from the range of between 1 μm and 40 μm, wherein, due to a measure taken during the production relating to the formation of the first layer and/or a provision and/or suitable formation of a layer different from the first layer, the proportion of the light reflected from the electrically conductive elements is lower than it would be without the measure.

2. A multi-layer body with a number of electrically conductive elements, which are provided by electrically conductive material in first zones in at least a first layer and when seen in a top view extend in at least one direction of extension over a width of from the range of between 1 μm and 40 μm, wherein the reflectance of visible light with wavelengths from the range of from 400 nm to 800 nm at the electrically conductive elements in the mirror reflection
(a) is less than 75%, and/or
(b) has a difference of at most 50% from the reflectance of the multi-layer body in second zones without electrically conductive material outside of the first zones in the mirror reflection.

3. A multi-layer body according to claim 1, wherein the first layer has a surface relief structure with an average structure depth from the range of from 10 nm to 100 μm.

4. A multi-layer body according to claim 1, wherein the first layer is arranged on a support which, on a side facing towards the first layer, has a first surface relief structure with a structure depth that is large enough that the first layer, on the upper side facing away from the support, has a second, through-formed surface relief structure with a structure depth which is determined by the structure depth of the first surface relief structure, and has at least 10% of this structure depth.

5. A multi-layer body according to claim 4, wherein a lacquer layer on the support at least in areas between the conductive elements, which areas are different from the first zones, wherein the refractive index of the lacquer layer differs by at most 0.2 from the refractive index of the support.

6. A multi-layer body according to claim 4, wherein the support is multi-layered and has a substrate, on which a replication lacquer layer is arranged, into which the first surface relief structure is molded.

7. A multi-layer body according to claim 1, wherein the surface relief structure or the first surface relief structure is formed, at least in areas, as a matte structure a grating or a refractive structure.

8. A multi-layer body according to claim 1, wherein the first layer has a surface relief structure with correlation lengths and/or lateral extents in a range of between 50 nm and 150 μm.

9. A multi-layer body according to claim 1, wherein the first layer has a layer thickness of between 20 nm and 1 μm.

10. A multi-layer body according to claim 1, wherein a surface relief structure which is molded, at least in areas, into the first layer deflects the incident light from the mirror reflection by diffraction, scattering and/or reflection.

11. A multi-layer body according to claim 10, wherein the surface relief structure in the first layer is formed, at least in areas, as a matte structure, with correlation lengths of between 1 μm and 100 μm.

12. A multi-layer body according to claim 10, wherein the surface relief structure in the first layer is formed, at least in areas, as a diffractive structure.

13. A multi-layer body according to claim 10, wherein the surface relief structure in the first layer is formed, at least in areas, as a moth-eye structure, which is formed as a cross grating and/or a linear grating with a grating period from the range of from 100 nm to 400 nm and/or an average structure depth from the range of from 40 nm to 10 μm.

14. A multi-layer body according to claim 10, wherein the surface relief structure is a matte structure with stochastically distributed relief structures and/or stochastically selected relief parameters, which is formed as a statistical structure with lateral dimensions of from 50 nm to 400 nm and an average structure depth from the range of from 40 nm to 10 μm.

15. A multi-layer body according to claim 1, wherein the electrically conductive material of the first layer comprises metal, and wherein a non-metallic compound of this metal is arranged on the first layer.

16. A multi-layer body according to claim 15, further comprising a metal oxide on the metal of the first layer.

17. A multi-layer body according to claim 15, wherein the metal comprises silver or copper, and wherein metal sulfide is arranged on the metal of the first layer.

18. A multi-layer body according to claim 15, wherein the metal of the first layer is chromated.

19. A multi-layer body according to claim 15, wherein the metal of the first layer comprises aluminum which is anodized.

20. A multi-layer body according to claim 1, further comprising at least one metal layer on the first layer.

21. A multi-layer body according to claim 20, wherein the electrically conductive metal of the first layer comprises silver and the metal layer on top of it comprises chromium.

22. A multi-layer body according to claim 1, further comprising a colored layer on or underneath the first layer.

23. A multi-layer body according to claim 22, further comprising a support, on which the first layer is arranged, and to which, due to its chemical properties and/or its surface structure and/or a structured layer on between the support and the first layer, a material which provides the colored layer adheres more poorly than to the first layer.

24. A multi-layer body according to claim 22, wherein the colored layer comprises photoresist.

25. A multi-layer body according to claim 1, further comprising a semiconductor layer on or underneath the first layer.

26. A multi-layer body according to claim 25, wherein the semi-conductor layer consists of inorganic material.

27. A multi-layer body according to claim 25, wherein the semi-conductor layer consists of organic material.

28. A multi-layer body according to claim 15, further comprising an intermediate layer between the first layer and the colored layer or semiconductor layer or the layer of a non-metallic compound or the further metal layer.

29. A multi-layer body according to claim 1, wherein a layer which is light-impermeable in areas and light-permeable in areas and which is provided as a gelatin layer with silver and silver oxide particles or as a layer of ink is arranged underneath the first layer.

30. A multi-layer body according to claim 1, wherein the electrically conductive material comprises at least one from the group of silver, gold, copper, chromium, aluminum, an alloy of at least two of the above-named materials and doped semiconductor material.

31. A multi-layer body according to claim 1, wherein the electrically conductive elements are provided in the form of strip conductors which are linear, bent, punctiform and/or gridded.

32. A display device and/or touch panel device with a multi-layer body according to claim 31.

33. A glass pane with a multi-layer body according to claim 31 to provide a resistance wire functionality.

34. A process for the production of a multi-layer body with a number of electrically conductive elements, which are provided by electrically conductive material in at least one layer and when seen in a top view extend in at least one direction of extension over a width from the range of between 1 μm and 40 μm, wherein the electrically conductive material is applied on a support, and wherein a) the support has such a high surface roughness that this through-forms and determines the surface roughness of the first layer, and/or wherein b) the material providing the first layer is subjected to a treatment to increase its surface roughness.

35. A process according to claim 34, wherein a lacquer layer is applied to the support, the refractive index of which lacquer layer differs by at most 0.2 from the refractive index of the support.

36. A process according to claim 34, wherein the support is subjected to a treatment to increase its surface roughness, by mechanical brushing, calendering, ion beam treatment and/or plasma treatment.

37. A process according to claim 34, wherein the surface of the support becomes microstructured or nanostructured or an additional layer which is microstructured or nanostructured is applied to the support before the electrically conductive material for the first layer is applied.

38. A process according to claim 37, wherein
a) the structuring takes place as thermal stamping or by stamping using ultraviolet radiation, and/or wherein
b) the additional layer is sprayed on, is applied by inkjet printing and/or another printing process, and/or wherein
c) the additional layer is first applied at least in one partial area over the whole surface and is then structured using photoresist.

39. A process according to claim 34, wherein the first layer is treated chemically, by laser and/or mechanically by rubbing, sanding and/or brushing.

40. A process according to claim 34, wherein a treatment of the material providing the first layer takes place before a structuring of the electrically conductive elements.

41. A process according to claim 34, wherein a treatment of the material providing the first layer takes place after a structuring to form the electrically conductive elements.

42. A process for the production of a multi-layer body with a number of electrically conductive elements which are provided by metal in at least a first layer and when seen in a top view extend in at least one direction of extension over a width from the range of between 1 μm and 40 μm, wherein
a) a surface of the metal for the first layer is chemically treated so that it appears darker and/or scatters the light more pronouncedly, and/or wherein
b) a further layer is provided over and/or underneath the first layer which appears darker and/or scatters light more pronouncedly than the metal of the first layer.

43. A process according to claim 42, wherein the metal is subjected to a redox reaction.

44. A process according to claim 43, wherein a reactant for the redox reaction is fed in from outside.

45. A process according to claim 43, wherein the metal is applied to an underlayer which comprises a reactants for the redox reaction.

46. A process according to claim 45, wherein the release of the reactants from the underlayer is brought about by the action of heat and/or waiting for a predetermined period.

47. A process according to claim 42, wherein the further layer is applied by coating, printing, doctor-blading and/or centrifuging.

48. A process according to claim 42, wherein the further layer is promoted to deposit selectively on the metal, and wherein
a) a material for the further layer is selected which adheres to the surface of the metal of the first layer due to a selective chemical reaction, and/or
b) the further layer is provided by solid particles which adhere to the metal, and/or
c) a support for the first layer, onto which this is applied, the metal for the first layer and the material for the further layer match one another such that an adhesion behavior of the support ensures that the material for the further layer does not adhere to it and an adhesion behavior of the metal ensures that the material for the further layer adheres to it, wherein the material of the support and/or a microstructure or nanostructure on its surface determines the adhesion behavior, and/or
d) the metal for the electrically conductive elements is heated to a temperature at which the material for the further layer melts, and/or
e) photoresist is used for a structuring.

49. A process according to claim 42, wherein the further layer is applied before a structuring of the metal layer and is structured together with this.

50. A process according to claim 49, wherein the further layer is provided in the form of photoresist for structuring, and the photoresist is left on the metal.

51. A process according to claim 42, wherein the further layer is applied after a structuring of the metal layer.

52. A process according to claim 51, wherein the further layer is provided in the form of photoresist, which is applied over the whole surface at least in areas, is exposed through the structured metal layer and is removed in the exposed area.

53. A process according to claim 42, wherein the further layer comprises a color layer, which is applied to a support before the metal for the first layer and is structured, and wherein the metal is only applied to the structured parts.

54. A process according to claim 42, wherein the further layer is provided by a semiconductor material, which comprises zinc oxide or aluminum-doped zinc oxide.

55. A process according to claim 42, wherein an intermediate layer is applied between the application of the further layer and the application of the metal for the first layer.

56. A process for the production of a multi-layer body with a number of conductive elements, which are provided by silver and when seen in a top view extend in a direction of extension over a width in the range of between 1 μm and 40 μm, wherein the silver, together with paraffin oil or silicone oil, is evaporated and it is caused to be deposited on a support.

57. A process for the production of a multi-layer body with a number of electrically conductive elements, which are provided by electrically conductive material in at least a first layer and when seen in a top view extend in at least one direction of extension over a width in the range of between 1 μm and 40 μm, wherein a masking layer with light-impermeable areas and light-permeable areas is applied to a support and wherein either a) a photoresist layer is applied to the masking layer a metal layer is applied to the masking layer and a photoresist layer onto this, and wherein in the photoresist is exposed through the masking layer and is removed in the exposed areas.

58. A process for the production of a multi-layer body, according to claim 34, wherein a) a surface of the metal for the first layer is chemically treated so that it appears darker and/or scatters the light more pronouncedly, and/or wherein b) a further layer is provided over and/or underneath the first layer which appears darker and/or scatters light more pronouncedly than the metal of the first layer.

59. A process according to claim 34, wherein a multi-layer body is transferred to a carrier substrate as a whole, wherein the layer provided most recently is contiguous to the carrier substrate.
